(19) United States
(12) Patent Application Publication
(10) Pub. No.: US 2018/0191198 A1
(43) Pub. Date: Jul. 5, 2018

(54) WIRELESS POWER TRANSMITTER

(71) Applicant: Samsung Electro-Mechanics Co., Ltd., Suwon-si (KR)

(72) Inventors: Doo Young SONG, Suwon-si (KR); Min Ho HEO, Suwon-si (KR)

(73) Assignee: Samsung Electro-Mechanics Co., Ltd., Suwon-si (KR)

(21) Appl. No.: 15/674,657

(22) Filed: Aug. 11, 2017

(30) Foreign Application Priority Data
Dec. 29, 2016 (KR) 10-2016-0182108

(51) Int. Cl. H02J 50/10; H02J 7/02; H01Q 7/00; H05K 7/14

(52) U.S. Cl. CPC H02J 50/10; H05K 7/1427; H01Q 7/00; H02J 7/025

(57) ABSTRACT

A wireless power transmitter includes: a case; a power transmission coil disposed in the case and configured to wirelessly transmit power; and a coupling antenna coil disposed in the case, wherein an outer diameter of the coupling antenna coil is greater than an outer diameter of the power transmission coil.

### CROSS-REFERENCE TO RELATED APPLICATIONS

This application claims benefit under 35 U.S.C. § 119(a) of Korean Patent Application No. 10-2016-0182108, filed on Dec. 29, 2016 in the Korean Intellectual Property Office, the entire disclosure of which is incorporated herein by reference for all purposes.

### BACKGROUND

### 1. Field

The present disclosure relates to a wireless power transmitter.

### 2. Description of Related Art

In accordance with the development of wireless technology, various wireless functions range from the transmission of data to the transmission of power. A wireless power transmission technology capable of charging an electronic device with the power even in a non-contact state (e.g., a state in which the electronic device is not in physical contact with a wireless power transmitter) has recently been developed.

Since such a wireless power transmission technology transmits power using a magnetic field, the magnetic field may be exposed to the outside of a product. As a result, there is a problem in that it is difficult to satisfy a stability condition such as electromagnetic compatibility (EMC), or the like.

In order to solve the problem of satisfying a stability condition, conventional wireless transmission technology has applied an LC filter to process noise in a circuit. However, such a conventional technology has a problem in that it does not provide any effect on wire noise caused on a substrate due to the magnetic field, or wireless noise radiated around a coil.

Such a conventional technology may be appreciated with reference to Korean Patent Publication No. 10-1269226, Korean Patent Publication No. 10-1364185, and Korean Patent Laid-Open Publication No. 2015-0139731.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a wireless power transmitter includes: a case; a power transmission coil disposed in the case and configured to wirelessly transmit power; and a coupling antenna coil disposed in the case, wherein an outer diameter of the coupling antenna coil is greater than an outer diameter of the power transmission coil.

The case may include an upper case formed of a non-metal material, and a lower case formed of a metal material. The coupling antenna coil may be embedded in the upper case.

The lower case may be electrically connected to a ground. The coupling antenna coil may be electrically connected to the lower case, and may be connected to the ground.

The coupling antenna coil may be disposed on a plane parallel to a plane of the power transmission coil.

The wireless power transmitter may further include a substrate embedded in the case, wherein the coupling antenna coil is printed on the substrate.

A center of the coupling antenna coil and a center of the power transmission coil may be in a same position or spaced apart within a predetermined range.

The power transmission coil may be disposed inside the outer diameter of the coupling antenna coil.

The wireless power transmitter may further include: a circuit board; and a magnetic body plate disposed on a top surface of the circuit board, wherein the power transmission coil is disposed on a top surface of the magnetic body plate.

The coupling antenna coil may be configured to block a part of a magnetic field generated by the power transmission coil to prevent the magnetic field from affecting the circuit board.

An inner diameter of the coupling antenna coil may be less than an inner diameter of the power transmission coil.

In another general aspect, a wireless power transmitter includes: a case; a circuit board disposed in the case; a power transmission coil formed on a surface of the circuit board and configured to wirelessly transmit power; and a coupling antenna coil disposed on the circuit board, wherein an outer diameter of the coupling antenna coil is greater than an outer diameter of the power transmission coil.

The wireless power transmitter may further include a magnetic body plate disposed on a top surface of the circuit board and included inside the coupling antenna coil, wherein the power transmission coil is disposed on a top surface of the magnetic body plate.

The coupling antenna coil may be disposed along an outer portion of the circuit board.

The case may include an upper case formed of a non-metal material, and a lower case formed of a metal material. The coupling antenna coil may be embedded in the upper case.

The lower case may be electrically connected to a ground. The coupling antenna coil may be electrically connected to the lower case, and may be connected to the ground.

A center of the coupling antenna coil and a center of the power transmission coil may be in a same position or radially spaced apart within a predetermined range.

The coupling antenna coil may be printed on the circuit board.

Other features and aspects will be apparent from the following detailed description, the drawings, and the claims.

### BRIEF DESCRIPTION OF DRAWINGS

FIG. 1 is a diagram illustrating an application of a wireless power transmitter, according to an embodiment.

FIG. 2 is a block diagram illustrating the wireless power transmitter of FIG. 1, according to an embodiment.

FIG. 3 is a block diagram illustrating a wireless charger of the wireless power transmitter of FIG. 2.

FIG. 4 is a perspective view illustrating a coupling antenna coil and a power transmission coil, according to an embodiment.

FIG. 5 is a plan view of the coupling antenna coil and the power transmission coil of FIG. 4.

FIG. 6 is a horizontal cross-sectional view of a wireless power transmitter, according to another embodiment.

FIG. 7 is a horizontal cross-sectional view of a wireless power transmitter, according to another embodiment.

FIG. 8 is a plan view illustrating a coupling antenna coil of the wireless power transmitter of FIG. 7.

FIG. 9 is a horizontal cross-sectional view of a wireless power transmitter, according to another embodiment.

FIG. 10 is a plan view illustrating a coupling antenna coil and a power transmission coil of the wireless power transmitter of FIG. 9.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

The features of the examples described herein may be combined in various ways as will be apparent after an understanding of the disclosure of this application. Further, although the examples described herein have a variety of configurations, other configurations are possible as will be apparent after an understanding of the disclosure of this application.

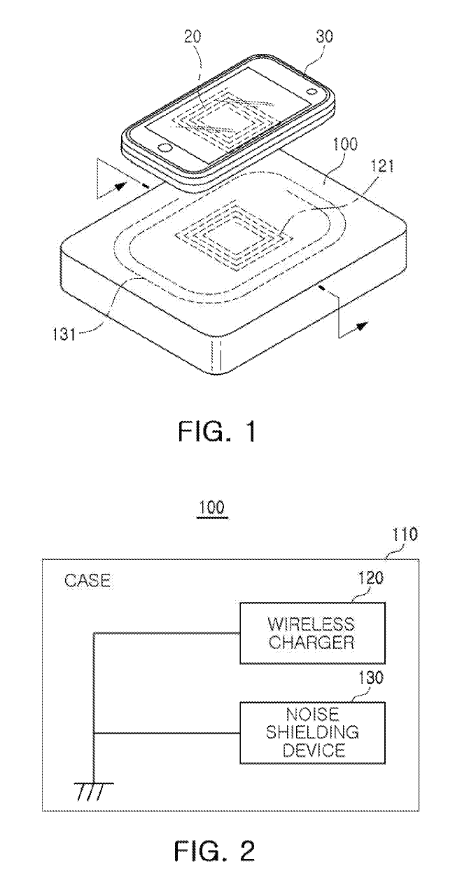

FIG. 1 is a diagram illustrating an application of a wireless power transmitter 100, according to an embodiment.

As illustrated in FIG. 1, the wireless power transmitter 100 wirelessly transmits power to a wireless power receiver 20.

The wireless power transmitter 100 includes, for example, a power transmission coil 121, and the power transmission coil 121 is magnetically coupled to a reception coil of the wireless power receiver 20 to wirelessly transmit the power to the wireless power receiver 20.

The wireless power receiver 20 is configured to be coupled to an electronic device 30 or to be integral thereto, and is configured to charge a battery of the electronic device 30 using the power received from the wireless power transmitter 100.

The wireless power transmitter 100 includes a coupling antenna coil 131 for shielding noise. That is, the coupling antenna coil 131 is configured to block noise caused in the wireless power transmitter 100 by a part of a magnetic field generated by the power transmission coil 121.

Hereinafter, various embodiments of wireless power transmitters and components thereof will be described in more detail with reference to FIGS. 2 through 10.

FIG. 2 is a block diagram illustrating the wireless power transmitter 100, according to an embodiment.

Referring to FIG. 2, the wireless power transmitter 100 includes a wireless charger 120 and a noise shielding device 130. The wireless charger 120 and the noise shielding device 130 may be included within a case 110.

The noise shielding device 130 is connected to a ground to allow the noise to flow into the ground, and the wireless charger 120 and the noise shielding device 130 commonly use the ground as illustrated, according to an embodiment.

The noise shielding device 130 includes the coupling antenna coil 131 illustrated in FIG. 1, which is an antenna type coil, and blocks the noise caused by a part of the magnetic field generated by the wireless charger 120 by inducing the part of the magnetic field to the ground using the coupling antenna coil 131.

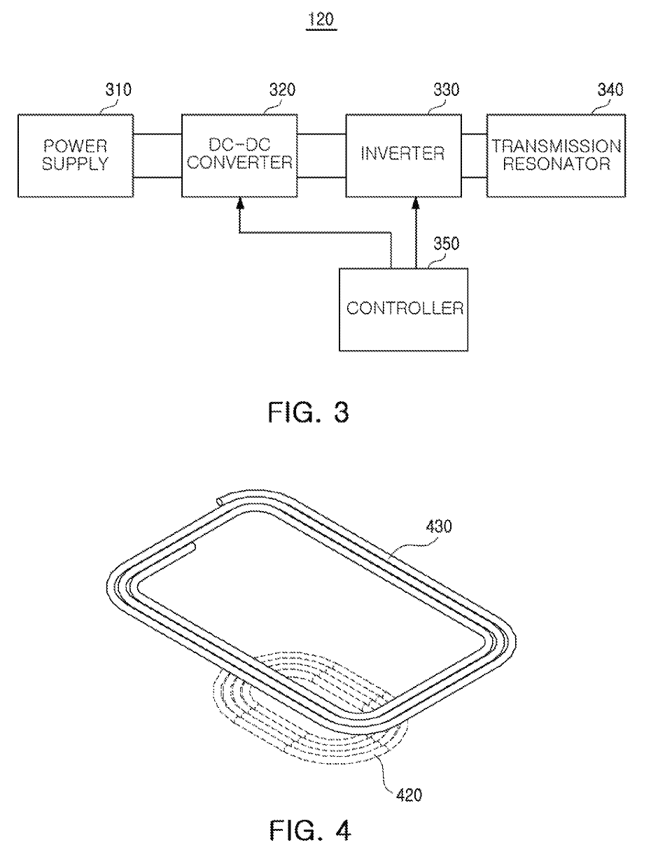

FIG. 3 is a block diagram illustrating the wireless charger 120.

Referring to FIG. 3, the wireless charger 120 includes a direct current (DC)-DC converter 320, an inverter 330, a transmission resonator 340, and a controller 350. According to an embodiment, the wireless charger 120 further includes a power supply 310.

The power supply 310 transforms power input from a source external to the wireless power transmitter 100 and outputs the transformed power. For example, the power supply 310 is a power adapter that receives commercial alternating current (AC) power and outputs a predetermined level of DC power. The power output from the power supply 310 is provided to the DC-DC converter 320. According to an embodiment, the power supply 310 adjusts a level of an output DC voltage in response to a control of the controller 350.

The DC-DC converter 320 converts the received power into a predetermined or set level of DC power. For example, the DC-DC converter 320 is a boost converter that boosts and a level of the received DC power and outputs a DC power having an increased level of power.

The inverter 320 outputs an alternating current from the DC power provided by the DC-DC converter 320 sand provides the alternating current to the transmission resonator 340, in response to the control of the controller 350.

The transmission resonator 340 resonates by the alternating current provided by the inverter 330 to wirelessly transmit the power.

The controller 350 controls an operation of the power supply 310 or the inverter 330.

The controller 350 may be implemented as a processor. According to an embodiment, the controller 350 may further include a memory or a storage device. For example, the processor may include a central processing unit (CPU), a graphic processing unit (GPU), a microprocessor, an application specific integrated circuit (ASIC), field programmable gate arrays (FPGA), and the like, and may have a multiple cores. The memory may be a volatile memory (e.g., a random access memory (RAM), or the like), a non-volatile memory (e.g., a read only memory (ROM), a flash memory, or the like), or a combination of a volatile memory and a non-volatile memory.

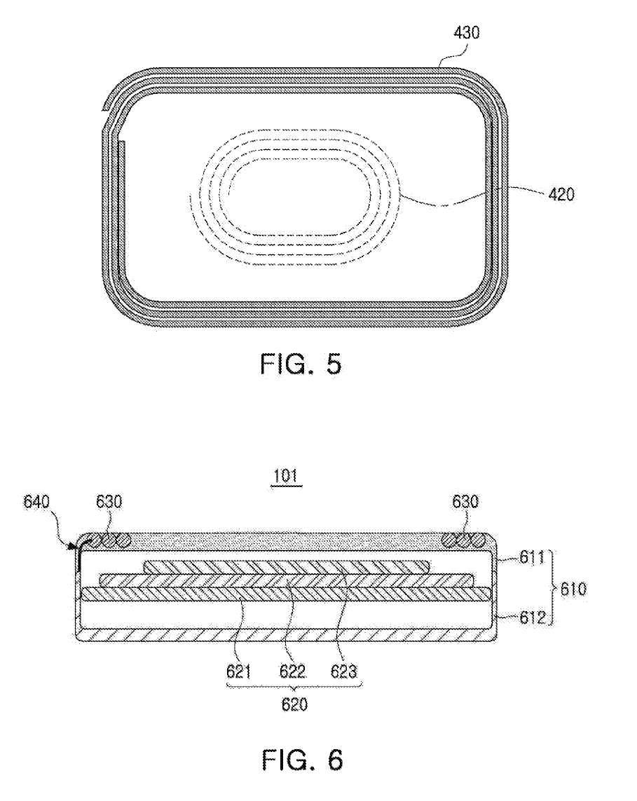

FIG. 4 is a perspective view illustrating a coupling antenna coil 430 and a power transmission coil 420, according to an embodiment. FIG. 5 is a plan view of the coupling antenna coil 430 and the power transmission coil 420.

A coupling antenna coil 430 includes a coil which is wound multiple times and may be connected to a ground. The coupling antenna coil 430 is formed around the power transmission coil 420, for example. That is, the coupling antenna coil 430 may be disposed partially or completely outside of an outer perimeter of the power transmission coil 420.

In the illustrated example, the coupling antenna coil 430 is formed on a plane parallel to a plane of the power transmission coil 420. Therefore, the coupling antenna coil 430 is disposed between the power transmission coil and a power reception coil (not shown), and couples to the ground a part of an outer magnetic field that is not coupled to the power transmission coil 420, of a magnetic field emitted from the power transmission coil 420, to block noise caused in the wireless power transmitter or the wireless power receiver by the part of the outer magnetic field.

The coupling antenna coil 430 is larger than the power transmission coil 420. That is, an outer diameter of the coupling antenna coil 430 is greater than an outer diameter of the power transmission coil 420. Thus, the coupling antenna coil 430, due to having the outer diameter greater than that of the power transmission coil 420, couples to the ground the part of the outer magnetic field that causes the noise in the wireless power transmitter, of the magnetic field generated by the power transmission coil 420. In this case, it may be more efficient for the center of the coupling antenna coil 430 and the center of the power transmission coil 420 to be the same (e.g., in a same position in a radial direction of the coupling antenna coil 430 and the center of the power transmission coil 420) or adjacent to each other within a predetermined range in the radial direction.

According to an embodiment, the coupling antenna coil 430 may partially overlap with the power transmission coil 420 in a plan view. That is, the outer diameter of the coupling antenna coil 430 may be greater than the outer of the power transmission coil 420, and an inner diameter of the coupling antenna coil 430 may be less than an inner diameter of the power transmission coil 420. According to embodiment shown in FIGS. 4 and 5, in order to prevent degradation of power transmission efficiency, a spacing of the coupling antenna coil or a thickness thereof (e.g., in a case in which the coupling antenna coil 430 is formed in a printed circuit board (PCB) pattern, a width of the pattern) may be adjusted so as not to degrade the power transmission efficiency of the power transmission coil 420.

FIG. 6 is a horizontal cross-sectional view of a wireless power transmitter 101, according to another embodiment.

Referring to FIG. 6, the wireless power transmitter 101 includes a case 610, a wireless charger 620, and a coupling antenna coil 630.

The wireless charger 620 includes a power transmission coil 623 and is disposed within the case 610. The coupling antenna coil 630 is disposed in the case 610.

As an example, the case 610 includes an upper case 611 formed of a non-metal material so that a magnetic field can be transmitted, and a lower case 612 formed of a metal material. The coupling antenna coil 630 is embedded in the upper case 611.

The wireless charger 620 includes a circuit board 621, a magnetic body plate 622 formed on a top surface of the circuit board, and a power transmission coil 623 formed on a top surface of the magnetic body plate 622. In the illustrated example, the power transmission coil 623 includes a single coil, but this configuration is merely illustrative, and the power transmission coil 623 may include multiple coils.

The coupling antenna coil 630 is formed over the power transmission coil 623, on a plane parallel to a plane of the power transmission coil 623. An outer diameter of the coupling antenna coil 630 is greater than an outer diameter of the power transmission coil 623.

In the illustrated example, the coupling antenna coil 630 blocks a part of a magnetic field generated from the power transmission coil 623 that may affect the circuit board 621, and thus blocks noise that may be caused in the wireless power transmitter 101 by the magnetic field.

The lower case 612 may be electrically connected to a ground, and the coupling antenna coil 630 is electrically connected to the lower case 612 through a conductive line 640 to be grounded.

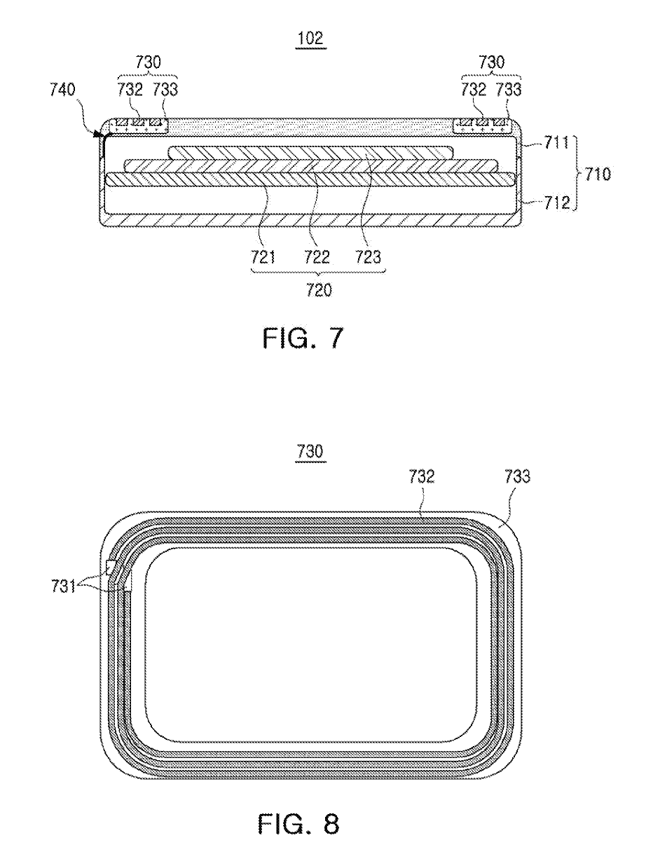

FIG. 7 is a horizontal cross-sectional view of a wireless power transmitter 102, according to another embodiment. FIG. 8 is a plan view illustrating the coupling antenna coil 102.

Referring to FIGS. 7 and 8, a wireless power transmitter 102 includes a case 710, a wireless charger 720, and a coupling antenna coil assembly 730. The coupling antenna coil assembly 730 includes a substrate 733, a coupling antenna coil 732, and terminals 731.

The wireless charger 720 is disposed within the case 710, and the coupling antenna coil assembly 730 is disposed in the case 710.

The case 710 includes an upper case 711 formed of a non-metal material so that a magnetic field may be transmitted, and a lower case 712 formed of a metal material.

The substrate 733 is embedded in the upper case 711, and the coupling antenna coil 732 is printed on the substrate 733. The terminals 731 are formed at both ends of the coupling antenna coil 732, and the terminals 731 are electrically connected to the lower case 712 through a conductive line 740, and are grounded.

The wireless charger 720 includes a circuit board 721, a magnetic body plate 722 disposed on a top surface of the circuit board, and a power transmission coil 723 disposed on a top surface of the magnetic body plate.

An outer diameter of the coupling antenna coil 730 is greater than an outer diameter of the power transmission coil 723. As a result, the coupling antenna coil 730 blocks noise that may be caused in the wireless power transmitter 102 by the magnetic field generated by the power transmission coil 723, by blocking a part of the magnetic field that may affect the circuit board 721.

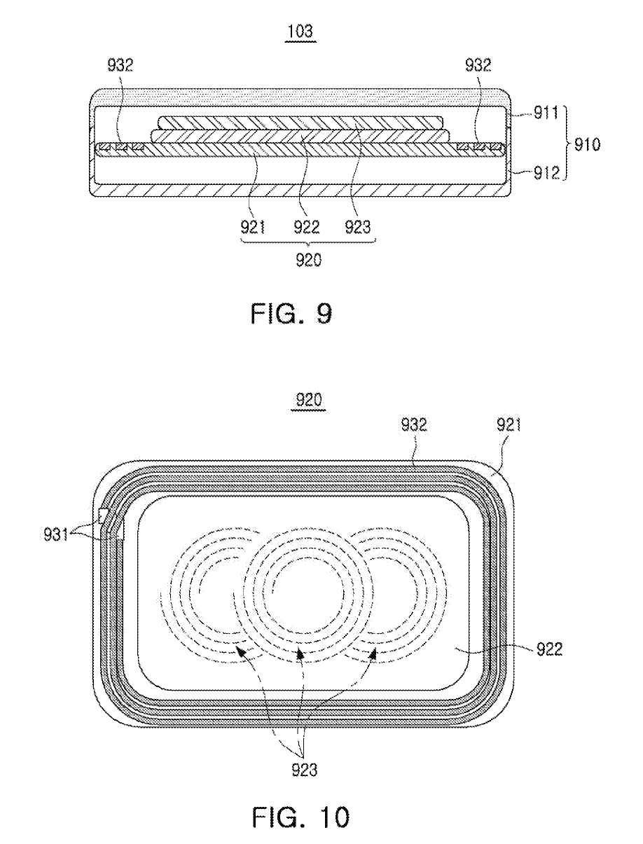

FIG. 9 is a horizontal cross-sectional view of a wireless power transmitter 103, according to another embodiment. FIG. 10 is a plan view illustrating a coupling antenna coil 932 and a power transmission coil 923 of the wireless power transmitter 103.

Referring to FIGS. 9 and 10, the wireless power transmitter 103 includes a case 910, a wireless charger 920, and a coupling antenna coil 932.

The wireless charger 920 is disposed within the case 910.

The wireless charger 920 includes a circuit board 921, a magnetic body plate 922 disposed on a top surface of the circuit board, and a power transmission coil 923 disposed on a top surface of the magnetic body plate. The magnetic body plate 922 is disposed inside the coupling antenna coil 932.

As shown in FIG. 10, in the illustrated example, the power transmission coil 923 includes multiple coils. However, the number of coils illustrated in the power transmission coil 923 is merely illustrative, and the power transmission coil 923 may include more or fewer coils than illustrated in FIG. 10.

The coupling antenna coil 932 is formed on the circuit board 921. For example, the coupling antenna coil 932 is printed on the circuit board 921. As an example, the coupling antenna coil 932 is formed along an outer portion of the circuit board 921 as illustrated, and terminals 931 are formed at both ends of the coupling antenna coil 932. The terminals 931 is connected to a ground within the circuit board, and the coupling antenna coil 932 is grounded.

The case 910 includes an upper case 911 formed of a non-metal material so that a magnetic field may be transmitted, and a lower case 912 formed of a metal material. The lower case 912 is connected to the ground of the circuit board 921.

In the embodiments described above with reference to FIGS. 6 through 10, an example is described in which the coupling antenna coil includes a single coil which is wound multiple times. However, the coupling antenna coil may include multiple coils. For example, the coupling antenna coil 630 described in FIG. 6 and the coupling antenna coil 932 described in FIG. 9 may be combined with each other so as to be variously modified.

As set forth above, according to the embodiments disclosed herein, a wireless power transmitter effectively reduces the noise caused by the magnetic field.

In addition, a wireless power transmitter according to embodiments disclosed herein effectively blocks the noise caused by magnetic field emission even with a simple and downsized structure, and therefore increases efficiency of power transmission by the magnetic field.

The controller 350 in FIG. 3 that performs the operations described in this application is implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access memory (RAM), flash memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A wireless power transmitter, comprising:
a case;
a power transmission coil disposed in the case and configured to wirelessly transmit power; and
a coupling antenna coil disposed in the case,
wherein an outer diameter of the coupling antenna coil is greater than an outer diameter of the power transmission coil.

2. The wireless power transmitter of claim 1, wherein
the case comprises
an upper case formed of a non-metal material, and
a lower case formed of a metal material, and
the coupling antenna coil is embedded in the upper case.

3. The wireless power transmitter of claim 2, wherein
the lower case is electrically connected to a ground, and
the coupling antenna coil is electrically connected to the lower case, and is connected to the ground.

4. The wireless power transmitter of claim 1, wherein the coupling antenna coil is disposed on a plane parallel to a plane of the power transmission coil.

5. The wireless power transmitter of claim 1, further comprising:
a substrate embedded in the case, wherein the coupling antenna coil is printed on the substrate.

6. The wireless power transmitter of claim 1, wherein a center of the coupling antenna coil and a center of the power transmission coil are in a same position or spaced apart within a predetermined range.

7. The wireless power transmitter of claim 6, wherein the power transmission coil is disposed inside the outer diameter of the coupling antenna coil.

8. The wireless power transmitter of claim 1, further comprising:
a circuit board; and
a magnetic body plate disposed on a top surface of the circuit board,
wherein the power transmission coil is disposed on a top surface of the magnetic body plate.

9. The wireless power transmitter of claim 8, wherein the coupling antenna coil is configured to block a part of a magnetic field generated by the power transmission coil to prevent the magnetic field from affecting the circuit board.

10. The wireless power transmitter of claim 1, wherein an inner diameter of the coupling antenna coil is less than an inner diameter of the power transmission coil.

11. A wireless power transmitter, comprising:
a case;
a circuit board disposed in the case;
a power transmission coil formed on a surface of the circuit board and configured to wirelessly transmit power; and
a coupling antenna coil disposed on the circuit board,
wherein an outer diameter of the coupling antenna coil is greater than an outer diameter of the power transmission coil.

12. The wireless power transmitter of claim 11, further comprising:
a magnetic body plate disposed on a top surface of the circuit board and included inside the coupling antenna coil,
wherein the power transmission coil is disposed on a top surface of the magnetic body plate.

13. The wireless power transmitter of claim 11, wherein the coupling antenna coil is disposed along an outer portion of the circuit board.

14. The wireless power transmitter of claim 11, wherein
the case comprises
an upper case formed of a non-metal material, and
a lower case formed of a metal material, and
the coupling antenna coil is embedded in the upper case.

15. The wireless power transmitter of claim 14, wherein
the lower case is electrically connected to a ground, and
the coupling antenna coil is electrically connected to the lower case, and is connected to the ground.

16. The wireless power transmitter of claim 11, wherein a center of the coupling antenna coil and a center of the power transmission coil are in a same position or spaced apart within a predetermined range.

17. The wireless power transmitter of claim 11, wherein the coupling antenna coil is printed on the circuit board.
